(19) United States
(12) Patent Application Publication
(10) Pub. No.: US 2011/0120536 A1
(43) Pub. Date: May 26, 2011

(54) ROUGHNESS CONTROL OF A WAVELENGTH SELECTIVE REFLECTOR LAYER FOR THIN FILM SOLAR APPLICATIONS

(76) Inventors: DAPENG WANG, (US); Shuran Sheng, (US); Yong-Kee Chae, (US)

(21) Appl. No.: 12/623,277

(22) Filed: Nov. 20, 2009

(51) Int. Cl. H01L 31/0236; H01L 31/18

(52) U.S. Cl. 136/255; 438/71; 257/E31.13

(57) ABSTRACT

A method and apparatus for forming a roughened wavelength selective reflector layer are provided. In one embodiment, a method of forming a solar cell device includes forming a wavelength selective reflector layer between a first p-i-n junction and a second p-i-n junction formed on a substrate, and performing a post treatment process on the wavelength selective reflector layer to form the uneven surface with the roughness greater than 20 nm. In another embodiment, a photovoltaic device includes a wavelength selective reflector layer disposed between a first p-i-n junction and a second p-i-n junction formed on a substrate, wherein the wavelength selective reflector layer has an uneven surface having a surface roughness greater than 20 nm.

### BACKGROUND OF THE INVENTION

1. Field of the Invention

Embodiments of the present invention generally relate to solar cells and methods for forming the same. More particularly, embodiments of the present invention relate to a wavelength selective reflector layer formed in thin-film and crystalline solar cells.

2. Description of the Related Art

Solar cells convert solar radiation and other light into usable electrical energy. The energy conversion occurs as the result of the photovoltaic effect. Solar cells may be formed from crystalline material or from amorphous or micro-crystalline materials. Generally, there are two major types of solar cells that are produced in large quantities today, which are crystalline silicon solar cells and thin film solar cells. Crystalline silicon solar cells typically use either mono-crystalline substrates (i.e., single-crystal substrates of pure silicon) or a multi-crystalline silicon substrates (i.e., poly-crystalline or polysilicon). Additional film layers are deposited onto the silicon substrates to improve light capture, form the electrical circuits, and protect the devices. Suitable substrates include glass, metal, and polymer substrates. It has been found that the properties of thin-film solar cells degrade over time upon exposure to light, which can cause the device stability to be less than desired. Typical solar cell properties that may degrade are the fill factor (FF), short circuit current, and open circuit voltage (Voc).

Thin film silicon solar cells have gained a significant market share due to low-cost, large-area deposition of the amorphous-microcrystalline silicon absorber layers. Thin-film solar cells use thin layers of materials deposited on suitable substrates to form one or more p-n junctions. Generally, different material layers perform different functions formed in the solar cells. In some instances, some material layers may server as a light absorber layer that may have high light-trapping effect to absorb light in the absorber layer to generate high current. In contrast, some material layers are configured to reflect and scatter light to the solar cells formed on the substrate so as to assist light retaining in the solar cell for a longer time for current generation. However, absorption loss may often occurs when light transmitting through these reflective material layers, thereby adversely reducing overall electrical performance and conversion efficiency of the solar cell junctions formed on the substrate.

Therefore, there is a need for improved thin film solar cells and methods and apparatuses for forming the same in a factory environment. There is also a need for a process which will fabricate a solar cell so that the reflective material layers formed in the solar cell may scatter the incoming light to the adjacent solar cells, thus improving the conversion efficiency, high fill factor, high short circuit current, high open circuit voltage and device stability of the solar cell.

### SUMMARY OF THE INVENTION

Embodiments of the invention provide methods of forming a wavelength selective reflector layer between solar cells formed on a substrate with a high surface roughness. In one embodiment, a method of forming a solar cell device includes forming a wavelength selective reflector layer between a first p-i-n junction and a second p-i-n junction formed on a substrate, and performing a post treatment process on the wavelength selective reflector layer to form the uneven surface with the roughness greater than 20 nm.

In another embodiment, a photovoltaic device includes a wavelength selective reflector layer disposed between a first p-i-n junction and a second p-i-n junction formed on a substrate, wherein the wavelength selective reflector layer has an uneven surface having a surface roughness greater than 20 nm.

In yet another embodiment, a method of forming a solar cell device includes forming a TCO layer on a substrate, texturing the TCO layer to form a roughened surface thereon, wherein the roughened surface has a surface roughness greater than 22 nm, forming a first p-i-n junction on the TCO layer, forming a wavelength selective reflector layer on the first p-i-n junction, wherein the wavelength selective reflector layer is controlled to have a surface roughness greater than 20 nm, and forming a second p-i-n junction on the wavelength selective reflector layer.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 is a schematic side-view of a tandem junction thin-film solar cell having an wavelength selective reflector layer disposed between junctions according to one embodiment of the invention;

FIG. 2 is schematic side-view of a magnified view of an wavelength selective reflector layer disposed between junctions according to one embodiment of the invention;

FIG. 3 is a schematic side-view of a tandem junction thin-film solar cell having an wavelength selective reflector layer disposed between junctions according to another embodiment of the invention;

FIG. 4 is a schematic side-view of a tandem junction thin-film solar cell having an wavelength selective reflector layer disposed between junctions according to one embodiment of the invention; and

FIG. 5 is a cross-sectional view of an apparatus according to one embodiment of the invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Thin-film solar cells are generally formed from numerous types of films, or layers, put together in many different ways. Most films used in such devices incorporate a semiconductor element that may comprise silicon, germanium, carbon, boron, phosphorous, nitrogen, oxygen, hydrogen and the like. Characteristics of the different films include degrees of crystallinity, dopant type, dopant concentration, film refractive index, film extinction coefficient, film transparency, film absorption, and conductivity. Typically, most of these films can be formed by use of a chemical vapor deposition process, which may include some degree of ionization or plasma formation.

Charge generation during a photovoltaic process is generally provided by a bulk semiconductor layer, such as a silicon containing layer. The bulk layer is also sometimes called an intrinsic layer to distinguish it from the various doped layers present in the solar cell. The intrinsic layer may have any desired degree of crystallinity, which will influence its light-absorbing characteristics. For example, an amorphous intrinsic layer, such as amorphous silicon, will generally absorb light at different wavelengths from intrinsic layers having different degrees of crystallinity, such as microcrystalline silicon. For this reason, most solar cells will use both types of layers to yield the broadest possible absorption characteristics. In some instances, an intrinsic layer may be used as a buffer layer between two dissimilar layer types to provide a smoother transition in optical or electrical properties between the two layers.

The present invention provides methods for forming a wavelength selective reflector layer (WSR) layer with desired film surface roughness to assist scattering incoming light to adjacent junction cells. In one embodiment, the wavelength selective reflector layer (WSR) layer may be formed to have a desired film surface roughness by a surface treatment process, a dry etching process, a wet etching process, a particle spray process, a laser process, a mechanical process or any other suitable surface roughening process. In one embodiment, the wavelength selective reflector layer (WSR) layer is controlled to have a surface roughness greater than 20 nm, for example about greater than 30 nm, such as between about 40 nm and about 60 nm.

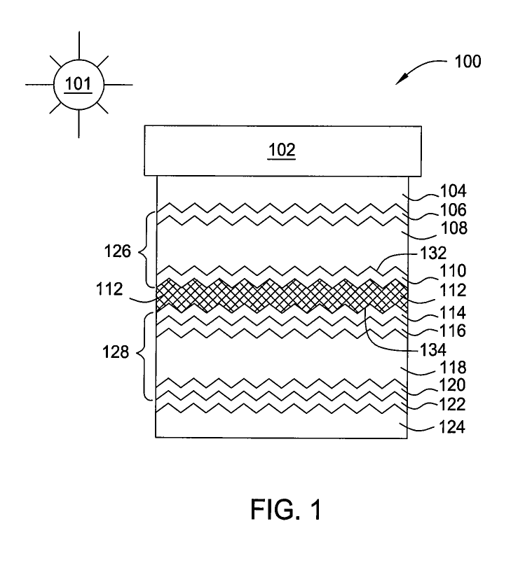

FIG. 1 is a schematic diagram of an embodiment of a multi-junction solar cell 100 oriented toward the light or solar radiation 101. Solar cell 100 comprises a substrate 102, such as a glass substrate, polymer substrate, metal substrate, or other suitable substrate, with thin films formed thereover. The solar cell 100 further comprises a first transparent conducting oxide (TCO) layer 104 formed over the substrate 102, a first p-i-n junction 126 formed over the first TCO layer 104. In one configuration, a wavelength selective reflector layer (WSR) layer 112 is formed over the first p-i-n junction 126. A second p-i-n junction 128 formed over the first p-i-n junction 126, a second TCO layer 122 formed over the second p-i-n junction 128, and a metal back layer 124 formed over the second TCO layer 122. In one embodiment, the WSR layer 112 is disposed between the first p-i-n junction 126 and the second p-i-n junction 128, and is configured to have film properties that improve light scattering and reflection for current generation in the formed solar cell 100. Additionally, the WSR layer 112 also provides a good p-n tunnel junction that has a high electrical conductivity and a tailored bandgap range that affect its transmissive and reflective properties to improve the formed solar cell's light conversion efficiency. Detail description of the WSR layer 112 will be further discussed below.

To improve light absorption by enhancing light trapping, the substrate and/or one or more of thin films formed thereover may be optionally textured by wet, plasma, ion, and/or mechanical processes. For example, in the embodiment shown in FIG. 1, the first TCO layer 104 is textured and the subsequent thin films deposited thereover will generally follow the topography of the surface below it.

In one embodiment, the first TCO layer 104 may be textured by a dry etching process, a wet etching process, a plasma process, a surface treatment process, or a mechanical process. In one embodiment, the surface roughness of the TCO layer 104 is controlled at greater than about 22 nm. The range of the surface roughness formed on the TCO layer 104 may be determined by the degree of surface roughness desired to form on the material layers subsequently formed on the TCO layer 104. As the degree of the surface roughness of the TCO layer 104 is greater, the surface roughness of the film layers subsequently formed thereover will also be enhanced and has greater film surface roughness. In one embodiment, the surface roughness of the TCO layer 104 is controlled at greater than 30 nm, such as greater than 40 nm, for example between about 60 nm and about 140 nm.

The first TCO layer 104 and the second TCO layer 122 may each comprise tin oxide, zinc oxide, indium tin oxide, cadmium stannate, combinations thereof, or other suitable materials. It is understood that the TCO materials may also include additional dopants and components. For example, zinc oxide may further include dopants, such as aluminum, gallium, boron, and other suitable dopants. Zinc oxide preferably comprises 5 atomic % or less of dopants, for example comprising 2.5 atomic % or less aluminum. In certain instances, the substrate 102 may be provided by the glass manufacturers with the first TCO layer 104 already provided.

The first p-i-n junction 126 may comprise a p-type amorphous silicon layer 106, an intrinsic type amorphous silicon layer 108 formed over the p-type amorphous silicon layer 106, and an n-type microcrystalline silicon layer 110 formed over the intrinsic type amorphous silicon layer 106. In certain embodiments, the p-type amorphous silicon layer 106 may be formed to a thickness between about 60 Å and about 300 Å. In certain embodiments, the intrinsic type amorphous silicon layer 108 may be formed to a thickness between about 1,500 Å and about 3,500 Å. In certain embodiments, the n-type microcrystalline semiconductor layer 110 may be formed to a thickness between about 100 Å and about 400 Å.

The WSR layer 112 disposed between the first p-i-n junction 126 and the second p-i-n junction 128 is configured to have certain desired film properties. In this configuration, the WSR layer 112 actively serves as an intermediate reflector layer having a desired refractive index, or ranges of refractive indexes and film surface roughness to reflect light received from the light incident side of the solar cell 100. The WSR layer 112 also serves as a junction layer that boosts the absorption of the short to mid wavelengths of light (e.g., 280 nm to 800 nm) in the first p-i-n junction 126 and improves short-circuit current, resulting in improved quantum and conversion efficiency. The WSR layer 112 further has high film transmittance for mid to long wavelengths of light (e.g., 500 nm to 1100 nm) to facilitate the transmission of light to the layers formed in the junction 128. Further, it is generally desirable for the WSR layer 112 to absorb as little light as possible while reflecting desirable wavelengths of light (e.g., shorter wavelengths) back to the layers in the first p-i-n junction 126 and transmitting desirable wavelengths of light (e.g., longer wavelengths) to the layers in the second p-i-n junction 128. Additionally, the WSR layer 112 can have a desirable bandgap and high film conductivity so as to efficiently conduct the generated current and allow electrons to flow from the first p-i-n junction 126 to the second p-i-n junction 128, and avoid blocking the generated current. The WSR layer 112 is desired to reflect shorter wavelength light back to the first p-i-n junction 126 while allowing substantially all of the longer wavelengths of light to pass to second p-i-n junction 128. By forming a WSR layer 112 that has a high film transmittance of desired wavelengths, a low film light absorption, desirable band gap properties (e.g., wide band gap range), and a high electrical conductivity the overall solar cell conversion efficiency may be improved.

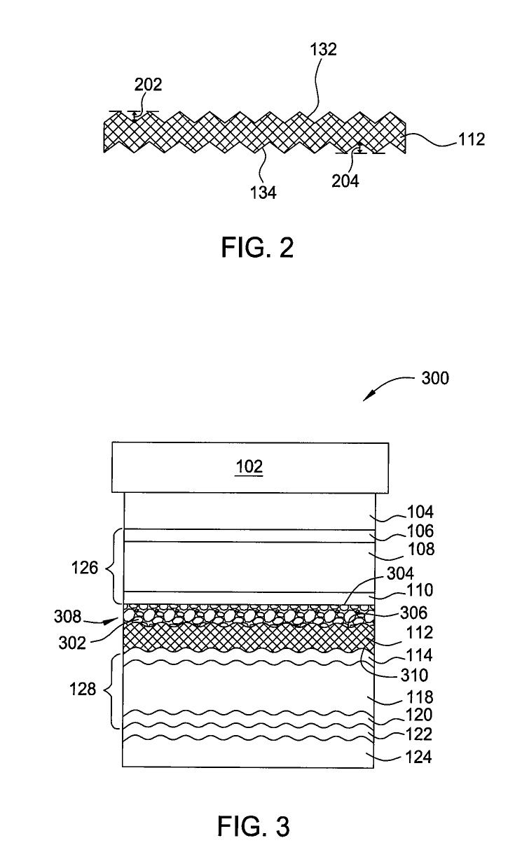

As the WSR layer 112 is desired to absorb light as little as possible to reduce absorption loss, the WSR layer 112 is configured to have a certain degree of film roughness formed on surfaces 132, 134 of the WSR layer 112. Roughness formed on the surfaces 132, 134 of the WSR layer 112 may assist light scattering and reflection passing through the WSR layer 112 to the adjacent junction cells 126, 128. It is believed that surface roughness formed on the WSR layer 112 may assist light scattering in the WSR layer 112, thereby increasing the likelihood of reflecting light back to the first p-i-n junction 126 and reducing absorption loss when light passes through the WSR layer 112. In one embodiment, the WSR layer 112 may have a surface roughness controlled greater than 20 nm, such as greater than 30 nm, for example, between about 40 nm and about 60 nm. It is noted that the surface roughness as described herein refers to an average number of surface roughness formed on the surface of the WSR layer 112. In one particular embodiment, the WSR layer 112 may have a surface roughness at about 47 nm, as the step height 202, 204 formed on the WSR layer surface 132, 134 shown in FIG. 2. In one embodiment, the roughness of the WSR layer 122 may be measured by an atomic force microscopy (AFM) conventionally available in the field.

In one embodiment, the WSR layer 112 may be a microcrystalline silicon layer having n-type or p-type dopants disposed within the WSR layer 112. In an exemplary embodiment, the WSR layer 112 is an n-type crystalline silicon alloy having n-type dopants disposed within the WSR layer 112. Different dopants disposed within the WSR layer 112 may also influence the WSR layer film optical and electrical properties, such as bandgap, crystalline fraction, conductivity, transparency, film refractive index, extinction coefficient, and the like. In some instances, one or more dopants may be doped into various regions of the WSR layer 112 to efficiently control and adjust the film bandgap, work function(s), conductivity, transparency and so on. In one embodiment, the WSR layer 112 is controlled to have a refractive index between about 1.4 and about 4, a bandgap of at least about 2 eV, and conductivity greater than about 0.3 S/cm.

In one embodiment, the WSR layer 112 may comprise an n-type doped silicon alloy layer, such as silicon oxide (SiO_{X}, SiO₂), silicon carbide (SiC), silicon oxynitride (SiON), silicon nitride (SiN), silicon carbon nitride (SiCN), silicon oxycarbide (SiOC), silicon oxycarbon nitride (SiOCN), or the like. In an exemplary embodiment, the WSR layer 112 is an n-type SiON or SiC layer.

Referring back to FIG. 1, the second p-i-n junction 128 may comprise a p-type microcrystalline silicon layer 114, and in some cases an optional p-i buffer type intrinsic amorphous silicon (PIB) layer 116 that is formed over the p-type microcrystalline silicon layer 114. Subsequently, an intrinsic type microcrystalline silicon layer 118 is formed over the p-type microcrystalline silicon layer 114, and an n-type amorphous silicon layer 120 formed over the intrinsic type microcrystalline silicon layer 118. In certain embodiments, the p-type microcrystalline silicon layer 114 may be formed to a thickness between about 100 Å and about 400 Å. In certain embodiments, the p-i buffer type intrinsic amorphous silicon (PIB) layer 116 may be formed to a thickness between about 50 Å and about 500 Å. In certain embodiments, the intrinsic type microcrystalline silicon layer 118 may be formed to a thickness between about 10,000 Å and about 30,000 Å. In certain embodiments, the n-type amorphous silicon layer 120 may be formed to a thickness between about 100 Å and about 500 Å.

The metal back layer 124 may include, but not limited to a material selected from the group consisting of Al, Ag, Ti, Cr, Au, Cu, Pt, alloys thereof, or combinations thereof. Other processes may be performed to form the solar cell 100, such a laser scribing processes. Other films, materials, substrates, and/or packaging may be provided over metal back layer 124 to complete the solar cell device. The formed solar cells may be interconnected to form modules, which in turn can be connected to form arrays.

Solar radiation 101 is primarily absorbed by the intrinsic layers 108, 118 of the p-i-n junctions 126, 128 and is converted to electron-hole pairs. The electric field created between the p-type layer 106, 114 and the n-type layer 110, 120 that stretches across the intrinsic layer 108, 118 causes electrons to flow toward the n-type layers 110, 120 and holes to flow toward the p-type layers 106, 114 creating a current. The first p-i-n junction 126 comprises an intrinsic type amorphous silicon layer 108 and the second p-i-n junction 128 comprises an intrinsic type microcrystalline silicon layer 118 since amorphous silicon and microcrystalline silicon absorb different wavelengths of the solar radiation 101. Therefore, the formed solar cell 100 is more efficient, since it captures a larger portion of the solar radiation spectrum. The intrinsic layer of amorphous silicon 108 and the intrinsic layer of microcrystalline silicon 118 are stacked in such a way that solar radiation 101 first strikes the intrinsic type layer if amorphous silicon 118 and transmitted through the WSR layer 112 and then strikes the intrinsic type microcrystalline silicon layer 118 since amorphous silicon has a larger bandgap than microcrystalline silicon. Solar radiation not absorbed by the first p-i-n junction 126 continuously transmits through the WSR layer 112 and continues on to the second p-i-n junction 128. The WSR layer 112 with the desired surface roughness greater than 20 nm will minimize light absorption and maximize light scattering and reflection to the adjacent junctions 126, 128.

The intrinsic amorphous silicon layer 108 may be deposited by providing a gas mixture of hydrogen gas to silane gas in a ratio by volume of about 20:1 or less. Silane gas may be provided at a flow rate by volume between about 0.5 sccm/L and about 7 sccm/L. Hydrogen gas may be provided at a flow rate by volume between about 5 sccm/L and 60 sccm/L. An RF power between 15 mW/cm² and about 250 mW/cm² may be provided to the showerhead. The pressure of the chamber may be maintained between about 0.1 Torr and 20 Torr, such as between about 0.5 Torr and about 5 Torr. The deposition rate of the intrinsic type amorphous silicon layer 108 will be about 100 Å/min or more. In an exemplary embodiment, the intrinsic type amorphous silicon layer 108 is deposited at a hydrogen to silane ratio at about 12.5:1.

The p-i buffer type intrinsic amorphous silicon (PIB) layer 116 may be deposited by providing a gas mixture of hydrogen gas to silane gas in a ratio by volume of about 50:1 or less, for example, less than about 30:1, for example between about 20:1 and about 30:1, such as about 25:1. Silane gas may be provided at a flow rate by volume between about 0.5 sccm/L and about 5 sccm/L, such as about 2.3 sccm/L. Hydrogen gas may be provided at a flow rate by volume between about 5 sccm/L and 80 sccm/L, such as between about 20 sccm/L and about 65 sccm/L, for example about 57 sccm/L. An RF power between 15 mW/cm² and about 250 mW/cm², such as between about 30 mW/cm² may be provided to the showerhead. The pressure of the chamber may be maintained between about 0.1 Torr and 20 Torr, preferably between about 0.5 Torr and about 5 Torr, such as about 3 Torr. The deposition rate of the PIB layer will be about 100 Å/min or more.

The intrinsic type microcrystalline silicon layer 118 may be deposited by providing a gas mixture of silane gas and hydrogen gas in a ratio by volume of hydrogen to silane between about 20:1 and about 200:1. Silane gas may be provided at a flow rate between about 0.5 sccm/L and about 5 sccm/L. Hydrogen gas may be provided at a flow rate by volume between about 40 sccm/L and about 400 sccm/L. In certain embodiments, the silane flow rate may be ramped up from a first flow rate to a second flow rate during deposition. In certain embodiments, the hydrogen flow rate may be ramped down from a first flow rate to a second flow rate during deposition. Applying RF power between about 300 mW/cm² or greater, preferably 600 mW/cm² or greater, at a chamber pressure between about 1 Torr and about 100 Torr, such as between about 3 Torr and about 20 Torr, for example between about 4 Torr and about 12 Torr, will generally deposit an intrinsic type microcrystalline silicon layer having crystalline fraction between about 20 percent and about 80 percent, such as between 55 percent and about 75 percent, at a rate of about 200 Å/min or more, for example about 500 Å/min. In some embodiments, it may be advantageous to ramp the power density of the applied RF power from a first power density to a second power density during deposition.

In another embodiment, the intrinsic type microcrystalline silicon layer 118 may be deposited in multiple steps, each having different crystal fraction. In one embodiment, for example, the ratio by volume of hydrogen to silane may be reduced in four steps from 100:1 to 95:1 to 90:1 and then to 85:1. In one embodiment, silane gas may be provided at a flow rate by volume between about 0.1 sccm/L and about 5 sccm/L, such as about 0.97 sccm/L. Hydrogen gas may be provided at a flow rate by volume between about 10 sccm/L and about 200 sccm/L, such as between about 80 sccm/L and about 105 sccm/L. In an exemplary embodiment wherein the deposition has multiple steps, such as four steps, the hydrogen gas flow may start at about 97 sccm/L in the first step, and be gradually reduced to about 92 sccm/L, 88 sccm/L, and 83 sccm/L respectively in the subsequent process steps. Applying RF power between about 300 mW/cm² or greater, such as about 490 mW/cm² at a chamber pressure between about 1 Torr and about 100 Torr, for example between about 3 Torr and about 20 Torr, such as between about 4 Torr and about 12 Torr, such as about 9 Torr, will result in deposition of an intrinsic type microcrystalline silicon layer at a rate of about 200 Å/min or more, such as 400 Å/min.

Charge collection is generally provided by doped semiconductor layers, such as silicon layers doped with p-type or n-type dopants. P-type dopants are generally Group III elements, such as boron or aluminum. N-type dopants are generally Group V elements, such as phosphorus, arsenic, or antimony. In most embodiments, boron is used as the p-type dopant and phosphorus as the n-type dopant. These dopants may be added to the p-type and n-type layers 106, 110, 114, 120 described above by including boron-containing or phosphorus-containing compounds in the reaction mixture. Suitable boron and phosphorus compounds generally comprise substituted and unsubstituted lower borane and phosphine oligomers. Some suitable boron compounds include trimethylboron (B(CH₃)₃ or TMB), diborane (B₂H₆), boron trifluoride (BF₃), and triethylboron (B(C₂H₅)₃ or TEB). Phosphine is the most common phosphorus compound. The dopants are generally provided with carrier gases, such as hydrogen, helium, argon, and other suitable gases. If hydrogen is used as the carrier gas, it adds to the total hydrogen in the reaction mixture. Thus hydrogen gas supply will include hydrogen used as a carrier gas for dopants.

Dopants will generally be provided as dilute gas mixtures in an inert gas. For example, dopants may be provided at molar or volume concentrations of about 0.5% in a carrier gas. If a dopant is provided at a volume concentration of 0.5% in a carrier gas flowing at 1.0 sccm/L, the resultant dopant flow rate will be 0.005 sccm/L. Dopants may be provided to a reaction chamber at flow rates between about 0.0002 sccm/L and about 0.1 sccm/L depending on the degree of doping desired. In general, dopant concentration is maintained between about 10¹⁸ atoms/cm³ and about 10²⁰ atoms/cm³.

In one embodiment, the p-type microcrystalline silicon layer 114 may be deposited by providing a gas mixture of hydrogen gas and silane gas in ratio by volume of hydrogen-to-silane of about 200:1 or greater, such as 1000:1 or less, for example between about 250:1 and about 800:1, and in a further example about 601:1 or about 401:1. Silane gas may be provided at a flow rate by volume between about 0.1 sccm/L and about 0.8 sccm/L, such as between about 0.2 sccm/L and about 0.38 sccm/L. Hydrogen gas may be provided at a flow rate by volume between about 60 sccm/L and about 500 sccm/L, such as about 143 sccm/L. TMB may be provided at a flow rate by volume between about 0.0002 sccm/L and about 0.0016 sccm/L, such as about 0.00115 sccm/L. If TMB is provided in a 0.5% molar or volume concentration in a carrier gas, then the dopant/carrier gas mixture may be provided at a flow rate between about 0.04 sccm/L and about 0.32 sccm/L, such as about 0.23 sccm/L. Applying RF power between about 50 mW/cm² and about 700 mW/cm², such as between about 290 mW/cm² and about 440 mW/cm², at a chamber pressure between about 1 Torr and about 100 Torr, such as between about 3 Torr and about 20 Torr, for example between 4 Torr and about 12 Torr, such as about 7 Torr or about 9 Torr, will deposit a p-type microcrystalline layer having crystalline fraction between about 20 percent and about 80 percent, such as between 50 percent and about 70 percent for a microcrystalline layer, at about 10 Å/min or more, such as about 143 Å/min or more.

In one embodiment, the p-type amorphous silicon layer 106 may be deposited by providing a gas mixture of hydrogen gas to silane gas in a ratio by volume of about 20:1 or less. Silane gas may be provided at a flow rate between about 1 sccm/L and about 10 sccm/L. Hydrogen gas may be provided at a flow rate between about 5 sccm/L and 60 sccm/L. Trimethylboron may be provided at a flow rate between about 0.005 sccm/L and about 0.05 sccm/L. If trimethylboron is provided in a 0.5% molar or volume concentration in a carrier gas, then the dopant/carrier gas mixture may be provided at a flow rate between about 1 sccm/L and about 10 sccm/L. Applying RF power between about 15 mWatts/cm² and about 200 mWatts/cm² at a chamber pressure between about 0.1 Torr and 20 Torr, such as between about 1 Torr and about 4 Torr, will deposit a p-type amorphous silicon layer at about 100 Å/min or more.

In on embodiment, the n-type microcrystalline silicon layer 110 may be deposited by providing a gas mixture of hydrogen gas to silane gas in a ratio by volume of about 100:1 or more, such as about 500:1 or less, such as between about 150:1 and about 400:1, for example about 304:1 or about 203:1. Silane gas may be provided at a flow rate between about 0.1 sccm/L and about 0.8 sccm/L, such as between about 0.32 sccm/L and about 0.45 sccm/L, for example about 0.35 sccm/L. Hydrogen gas may be provided at a flow rate between about 30 sccm/L and about 250 sccm/L, such as between about 68 sccm/L and about 143 sccm/L, for example about 71.43 sccm/L. Phosphine may be provided at a flow rate between about 0.0005 sccm/L and about 0.006 sccm/L, such as between about 0.0025 sccm/L and about 0.015 sccm/L, for example about 0.005 sccm/L. In other words, if phosphine is provided in a 0.5% molar or volume concentration in a carrier gas, then the dopant/carrier gas may be provided at a flow rate between about 0.1 sccm/L and about 5 sccm/L, such as between about 0.5 sccm/L and about 3 sccm/L, for example between about 0.9 sccm/L and about 1.088 sccm/L. Applying RF power between about 100 mW/cm² and about 900 mW/cm², such as about 370 mW/cm², at a chamber pressure of between about 1 Torr and about 100 Torr, such as between about 3 Torr and about 20 Torr, for example between 4 Torr and about 12 Torr, for example about 6 Torr or about 9 Torr, will deposit an n-type microcrystalline silicon layer having a crystalline fraction between about 20 percent and about 80 percent, such as between 50 percent and about 70 percent, at a rate of about 50 Å/min or more, such as about 150 Å/min or more.

In one embodiment, the n-type amorphous silicon layer 120 may be deposited by providing a gas mixture of hydrogen gas to silane gas in a ratio by volume of about 20:1 or less, such as about 5:5:1 or 7.8:1. Silane gas may be provided at a flow rate between about 0.1 sccm/L and about 10 sccm/L, such as between about 1 sccm/L and about 10 sccm/L, between about 0.1 sccm/L and 5 sccm/L, or between about 0.5 sccm/L and about 3 sccm/L, for example about 1.42 sccm/L or 5.5 sccm/L. Hydrogen gas may be provided at a flow rate between about 1 sccm/L and about 40 sccm/L, such as between about 4 sccm/L and about 40 sccm/L, or between about 1 sccm/L and about 10 sccm/L, for example about 6.42 sccm/L or 27 sccm/L. Phosphine may be provided at a flow rate by volume between about 0.0005 sccm/L and about 0.075 sccm/L, such as between about 0.0005 sccm/L and about 0.0015 sccm/L or between about 0.015 sccm/L and about 0.03 sccm/L, for example about 0.0095 sccm/L or 0.023 sccm/L. If phosphine is provided in a 0.5% molar or volume concentration in a carrier gas, then the dopant/carrier gas mixture may be provided at a flow rate by volume between about 0.1 sccm/L and about 15 sccm/L, such as between about 0.1 sccm/L and about 3 sccm/L, between about 2 sccm/L and about 15 sccm/L, or between about 3 sccm/L and about 6 sccm/L, for example about 1.9 sccm/L or about 4.71 sccm/L. Applying RF power between about 25 mW/cm² and about 250 mW/cm², such as about 60 mW/cm² or about 80 mW/cm², at a chamber pressure between about 0.1 Torr and about 20 Torr, such as between about 0.5 Torr and about 4 Torr, such as about 1.5 Torr, will deposit an n-type amorphous silicon layer at a rate of about 100 Å/min or more, such as about 200 Å/min or more, such as about 300 Å/min or about 600 Å/min.

In some embodiments, alloys of silicon with other elements such as oxygen, carbon, nitrogen, hydrogen, and germanium may be useful. These other elements may be added to silicon films by supplementing the reactant gas mixture with sources of each. Alloys of silicon may be used in any type of silicon layers, including p-type, n-type, PIB, WSR layer, or intrinsic type silicon layers. For example, carbon may be added to the silicon films by adding a carbon source such as methane (CH₄) to the gas mixture. In general, most C₁-C₄ hydrocarbons may be used as carbon sources. Alternately, organosilicon compounds known to the art, such as organosilanes, organosiloxanes, organosilanols, and the like may serve as both silicon and carbon sources. Germanium compounds such as germanes and organogermanes, along with compounds comprising silicon and germanium, such as silylgermanes or germylsilanes, may serve as germanium sources. Oxygen gas (O₂) may serve as an oxygen source. Other oxygen sources include, but are not limited to, oxides of nitrogen (nitrous oxide—N₂O, nitric oxide—NO, dinitrogen trioxide—N₂O₃, nitrogen dioxide—NO₂, dinitrogen tetroxide—N₂O₄, dinitrogen pentoxide—N₂O₅, and nitrogen trioxide—NO₃), hydrogen peroxide (H₂O₂), carbon monoxide or dioxide (CO or CO₂), ozone (O₃), oxygen atoms, oxygen radicals, and alcohols (ROH, where R is any organic or hetero-organic radical group). Nitrogen sources may include nitrogen gas (N₂), ammonia (NH₃), hydrazine (N₂H₂), amines (RₓNR′₃₋ₓ, where x is 0 to 3, and each R and R′ is independently any organic or hetero-organic radical group), amides ((RCO))ₓNR′₃₋ₓ, where x is 0 to 3 and each R and R′ is independently any organic or hetero-organic radical group), imides (RCONCOR′, where each R and R′ is independently any organic or hetero-organic radical group), enamines (R₁R₂C═C₃NR₄R₅, where each R₁-R₅ is independently any organic or hetero-organic radical group), and nitrogen atoms and radicals.

In one embodiment, the WSR layer 112 is an n-type crystalline silicon alloy layer formed over the n-type microcrystalline silicon layer 110. The n-type crystalline silicon alloy layer of the WSR layer 112 may be microcrystalline, nanocrystalline, or polycrystalline. The n-type crystalline silicon alloy WSR layer 112 may contain alloying elements, such as carbon, oxygen, nitrogen, or any combination thereof. It may be deposited as a single homogeneous layer, a single layer with one or more graduated characteristics, or as a stack of layers. The graduated characteristics may include crystallinity, dopant concentration (e.g., phosphorous), alloy material (e.g., carbon, oxygen, nitrogen) concentration, or other characteristics such as dielectric constant, refractive index, conductivity, or bandgap. The n-type crystalline silicon alloy WSR layer 112 may contain an n-type silicon carbide layer, an n-type silicon oxide layer, an n-type silicon nitride layer, and n-type silicon oxynitride layer, an n-type silicon oxycarbide layer, and/or an n-type silicon oxycarbonitride layer.

The quantities of secondary components in the n-type crystalline silicon alloy WSR layer 112 may deviate from stoichiometric ratios to some degree. For example, an n-type silicon carbide layer may have between about 1 atomic % and about 50 atomic % carbon. An n-type silicon nitride layer may likewise have between about 1 atomic % and about 50 atomic % nitrogen. An n-type silicon oxide layer may have between about 1 atomic % and about 50 atomic % oxygen. In an alloy comprising more than one secondary component, the content of secondary components may be between about 1 atomic % and about 50 atomic %, with silicon content between 50 atomic % and 99 atomic %. The quantity of secondary components may be adjusted by adjusting the ratios of precursor gases in the processing chamber. The ratios may be adjusted in steps to form layered structures, or continuously to form graduated single layers.

Carbon containing gas, such as methane (CH₄), may be added to the reaction mixture for depositing the n-type microcrystalline silicon layer to form an n-type microcrystalline silicon carbide WSR layer 112. In one embodiment, the ratio of carbon containing gas flow rate to silane flow rate is between about 0 and about 0.5, such as between about 0.20 and about 0.35, for example about 0.25. The ratio of carbon containing gas to silane in the feed may be varied to adjust the amount of carbon in the deposited film. The WSR layer 112 may be deposited in a number of layers, each having different carbon content, or the carbon content may be continuously adjusted through the deposited WSR layer 112. Moreover, the carbon and dopant content may be adjusted and graduated simultaneously within the WSR layer 112. Depositing the WSR layer 112 as a number of stacked layers has advantages in that each of the formed multiple layers can have a different refractive index that allows the multiple layer stack to operate as a Bragg reflector layer, significantly enhancing the reflectivity of the WSR layer 112 over a desired range of wavelengths, such as short to mid wavelengths.

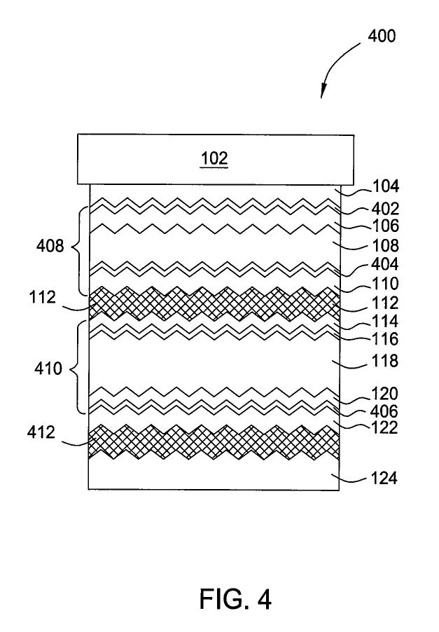

As discussed above, the n-type crystalline silicon alloy WSR layer 112 can provide several advantages. For example, the n-type crystalline silicon alloy WSR layer 112 can be positioned within at least three positions within a solar cell, such as act as a semi-reflective intermediate reflector layer, a second WSR reflector layer (e.g., reference numeral 412 in FIG. 4) or act as a junction layer. Inclusion of the n-type crystalline silicon alloy WSR layer 112 as a junction layer boosts absorption of short wavelength light by the first p-i-n junction 126 and improves short-circuit current, resulting in improved quantum and conversion efficiency. Furthermore, the n-type crystalline silicon alloy WSR layer 112 has desired optical and electrical film properties, such as high conductivity, bandgap and refractive index for desired reflectance and transmittance. Microcrystalline silicon carbide, for example, develops crystalline fraction above 60%, bandgap width above 2 electron-volts (eV), and conductivity greater than 0.01 Siemens per centimeter (S/cm). Moreover, it can be deposited at rates of 150-200 Å/min or higher with thickness variation less than 10%. The bandgap and refractive index can be adjusted by varying the ratio of carbon containing gas to silane in the reaction mixture. The adjustable refractive index allows formation of a reflective layer that is highly conductive and has a wide bandgap, resulting in an improved generated current.

The texture and/or roughness of the WSR layer 112 formed in the solar cell 100 may be formed by a dry etching process, a wet etching process, a surface treatment process, a light/gentle plasma process, a laser process, a particle spray process, a mechanical process or any other suitable process. Furthermore, the roughness of the WSR layer 112 may be created by texturing or precleaning a previous layer, such as the n-type microcrystalline silicon layer 110, the underlying TCO layer 104, or other previously formed layers 106, 108 in the first p-i-n junction 126 where the WSR layer 112 is formed on so when the WSR layer 112 is deposited thereon, the WSR layer 112 will grow and follow the topography of the layers to form an uneven surface with the desired roughness on the surface 134 of the WSR layer 112.

In one embodiment, a hydrogen or argon plasma pre-treat process may be performed to create a roughness surface on the underlying n-type microcrystalline silicon layer 110 as well as removing contaminants from the substrate surface so as to allow the WSR layer 112 subsequently formed thereon to create an uneven surface with desired roughness. In one embodiment, the pre-teat and/or pre-clean process may be performed by supplying hydrogen gas or argon gas to the processing chamber where the substrate 102 is loaded between about 10 sccm/L and about 45 sccm/L, such as between about 15 sccm/L and about 40 sccm/L, for example about 20 sccm/L and about 36 sccm/L. In one example, the hydrogen gas may be supplied at about 21 sccm/L or the argon gas may be supplied at about 36 sccm/L. The treatment is accomplished by applying RF power between about 10 mW/cm² and about 250 mW/cm², such as between about 25 mW/cm² and about 250 mW/cm², for example about 60 mW/cm² or about 80 mW/cm² for hydrogen treatment and about 25 mW/cm² for argon treatment.

Alternatively, a wet pre-cleaning process may be performed to create an uneven surface on the underlying n-type microcrystalline silicon layer 110 so the subsequently deposited WSR layer 112 can follow the topography of the uneven surface of the n-type microcrystalline silicon layer 110 to create the uneven surface, such as the surface 132, 134 of the WSR layer 112 with desired roughness, as shown in FIG. 2. In one embodiment, the wet pre-cleaning process may be performed by using a batch cleaning process in which the substrate 102 is exposed to a cleaning solution. The substrate can be cleaned using a wet cleaning process in which the surface 134 is sprayed, flooded, or immersed in a cleaning solution. The clean solution may be an SC1 cleaning solution, an SC2 cleaning solution, HF-last type cleaning solution, ozonated water solution, hydrofluoric acid (HF) and hydrogen peroxide (H₂O₂) solution, or other suitable and cost effective cleaning solution. The cleaning process may be performed on the substrate between about 5 seconds and about 600 seconds, such as about 30 seconds to about 240 second, for example about 120 seconds.

Alternatively, a post wet etching or post plasma treatment process, similar to the pre-cleaning process or pre-treat process described above, may be performed on the surface 134 of the WSR layer. The post wet etching or post plasma treatment process is performed directly on the surface 134 of the WSR layer 112 to create a desired roughness on the surface 134 of the WSR layer 112. In one embodiment, the post wet etching or post plasma treatment process may be performed to create the uneven surface 134 of the WSR layer 112 having a roughness 204 greater than 20 nm, such as greater than 30 nm, for example between about 40 nm and about 60 nm.

FIG. 3 is a schematic side-view of a tandem-junction thin-film solar cell 300 according to another embodiment of the invention. The embodiment of FIG. 3 differs from that of FIG. 1 by eliminating the optional texturing process performed on the first TCO layer 104 as described above. As a texturing process is not performed on the layers 104, 106, 108, 110 previously formed on the substrate 102 prior to the deposition of the WSR layer 112, the surface 304 where the WSR layer 112 will be deposited on the substantially flat surface 304 without a post deposition roughening process performed thereon. Accordingly, a thin layer 308 made up by particles 302 may be formed on the surface 304 of the n-type microcrystalline silicon layer 110 to create an uneven surface. Therefore, when the subsequently deposited WSR layer 112 is formed thereon, the WSR layer 112 will follow the uneven topography created by the thin layer 304 of particles, forming an uneven initial surface 306 and nucleation sites. Thus, the WSR layer 112 will follow the topography created by the initial surface 306 until a desired thickness of the WSR layer 112. At the end of the WSR layer deposition process, a final surface 310 formed on the WSR layer 112 may have a desired degree of roughness transferred from the particles of the thin layer 308 so as to scatter and reflect lights transmitted therethrough. In one embodiment, the outer surface 310 of the WSR layer 112 may have a roughness greater than 20 nm, such as greater than 30 nm, for example between about 40 nm and 60 nm.

In one embodiment, the particles 302 utilized to be sprayed on the surface 304 of the n-type microcrystalline silicon layer 110 may have a particle diameter between about 10 nm and about 100 nm. As the uneven topography of the thin layer 308 of particles 302 may be enhanced or diminished as the subsequent WSR layer 112 is formed thereon, the selection of the particle size may be varied as needed. In one embodiment, the particle size selected to create the thin layer 308 of particles 302 is about 10 nm. The particle 302 may be formed by a dielectric material, such as silica, silica powder, silicon oxide, silicon carbide, or other suitable silicon containing materials that can create a desired degree of surface roughness while not adversely affecting the electrical performance of the junction cells 126, 128. After the surface 310 of the WSR layer 112 has formed with a desired roughness, the layers 114, 118, 120, 112, 124 utilized to form the second p-i-n junction 128 and the back reflector layer will also follow the topography of the roughened surface 310 of the WSR layer 112 to form uneven surfaces.

FIG. 4 is a schematic side-view of a tandem-junction thin-film solar cell 400 according to another embodiment of the invention. The embodiment of FIG. 4 has similar structures of FIG. 1, having the first TCO layer 104 disposed on the substrate 102 and two formed p-i-n junctions 408, 410. The WSR layer 112 is disposed between the first p-i-n junction 408 and the second p-i-n junctions 410. In one embodiment, the WSR layer 112 may be an n-type doped silicon alloy layer, such as SiO₂, SiC, SiON, SiN, SiCN, SiOC, SiOCN or the like. In an exemplary embodiment, the WSR layer 112 is an n-type SiON or a n-type SiC layer.

The WSR layer 112 is formed to have a desired degree of surface roughness as described above with referenced to FIGS. 1-3. As discussed above, the roughness formed on the surface of the WSR layer 112 may be formed by performing texturing process on the previous layers, such as a TCO layer 104 or the n-type microcrystalline silicon layer 110 formed on the substrate 102 so the WSR layer 112 subsequently formed thereon will follow the textured surface formed previously to create the WSR layer 112 with the desired degree of roughness. Alternatively, the surface roughness of the WSR layer 112 may be formed by performing a pre-treatment or a pre-cleaning process prior to the deposition of the WSR layer 112. Furthermore, the surface roughness of the WSR layer 112 may be formed by performing a post-treatment or a post-cleaning process directly on the surface of the WSR layer 112 after the WSR layer 112 is formed on the n-type microcrystalline silicon layer 110. Additionally, as discussed above, the surface roughness of the WSR layer 112 may be formed by spraying a thin layer of particles on the substrate surface prior to the deposition of the WSR layer 112. Accordingly, as the WSR layer 112 is deposited thereon, the WSR layer 112 will follow the topography defined by the thin layer of particles, thereby creating the WSR layer 112 with desired film roughness.

Additionally, a second WSR layer 412, (e.g. a back reflector layer), may also be disposed between the second p-i-n junction 410 and the second TCO layer 122 or the metal back layer 124. The second WSR layer 412 may have similar film properties and film roughness as the first WSR layer 112, as discussed above. Just as the first WSR layer 112 desirably reflects short wavelengths of light back to the first p-i-n junction 408 and allows long wavelengths of light to pass to the second p-i-n cell 410, the second WSR layer 412 is configured to reflect the long wavelengths of light back to the second p-i-n junction 410 and have a low electrically resistance to promote current flow through to the second WSR layer 412. In one embodiment, the degree of roughness of the second WSR layer 412 may be configured to be similar to the degree of roughness of the first WSR layer 122 formed between the first and the second p-i-n junction 408, 410. In one embodiment, the surface roughness of the second WSR layer 412 is controlled greater than 20 nm, such as greater than 30 nm, for example between about 40 nm and about 60 nm, such as about 47 nm. In another embodiment, the second WSR layer 412 may be controlled having a surface roughness greater than 50 nm and less than 120 nm.

In one embodiment, the second WSR layer 412 has a high film conductivity and low refractive index for high film reflectance, while having low contact resistance to the second TCO layer 122. Accordingly, it is desirable to form a second WSR layer 412 that has a low contact resistance to its adjacent layers and low refractive index as well as a high reflectance. In the embodiment the second WSR layer 412 comprises a carbon doped n-type silicon alloy layer (SiC), since SiC layers typically have a higher conductivity as compared to an n-type silicon oxynitride (SiON) layer. In some cases, the first WSR layer 112 or the second WSR layer 412 is formed from an n-type SiON layer, since n-type SiON layers typically have a lower refractive index than an n-type SiC layers. In one embodiment, the first WSR layer 112 is desired to have a refractive index between about 1.4 and about 4, such as about 2, while the second WSR layer 412 is desired to have a refractive index between about 1.4 and about 4, such as about 2. The first WSR layer 112 is desired to have conductivity between about greater 10⁻⁹ S/cm and the second WSR layer 412 is desired to have conductivity about greater than 10⁻⁴ S/cm.

Similar to the first p-i-n junction 126 depicted in FIG. 1, the first p-i-n junction 408 includes the p-type amorphous silicon layer 106, the intrinsic type amorphous silicon layer 108 and the n-type microcrystalline silicon layer 110. A degeneratively-doped p-type amorphous silicon layer 402 (a heavily doped p-type amorphous silicon layer having a dopant concentration greater than p-type amorphous silicon layer 106) is formed over the conductive layer 104. Furthermore, an n-type amorphous silicon buffer layer 404 is formed between the intrinsic type amorphous silicon layer 108 and the n-type microcrystalline silicon layer 110. The n-type amorphous silicon buffer layer 404 is formed to a thickness between about 10 Å and about 200 Å. It is believed that the n-type amorphous silicon buffer layer 404 helps bridge the bandgap offset that is believed to exist between the intrinsic type amorphous silicon layer 108 and the n-type microcrystalline silicon layer 110. Thus, it is believed that cell efficiency is improved due to enhanced current collection, due to the addition of the n-type amorphous silicon buffer layer 404.

The second p-i-n junction 410, which is similar to the second p-i-n junction 128 of FIG. 1, comprises a p-type microcrystalline silicon layer 114, and an optional p-i buffer type intrinsic amorphous silicon (PIB) layer 116 that may be formed over the p-type microcrystalline silicon layer 114. Generally, the intrinsic type microcrystalline silicon layer 118 is formed over optional p-i buffer type intrinsic amorphous silicon (PIB) layer 116, and the n-type amorphous silicon layer 120 is formed over the intrinsic type microcrystalline silicon layer 118. Furthermore, a degeneratively-doped n-type amorphous silicon layer 406 may be formed primary as the heavily doped n-type amorphous silicon layer to provide improved ohmic contact with the second TCO layer 122. In one embodiment, the heavily doped n-type amorphous silicon layer 406 has a dopant concentration between about 10²⁰ atoms per cubic centimeter and about 10²¹ atoms per cubic centimeter.

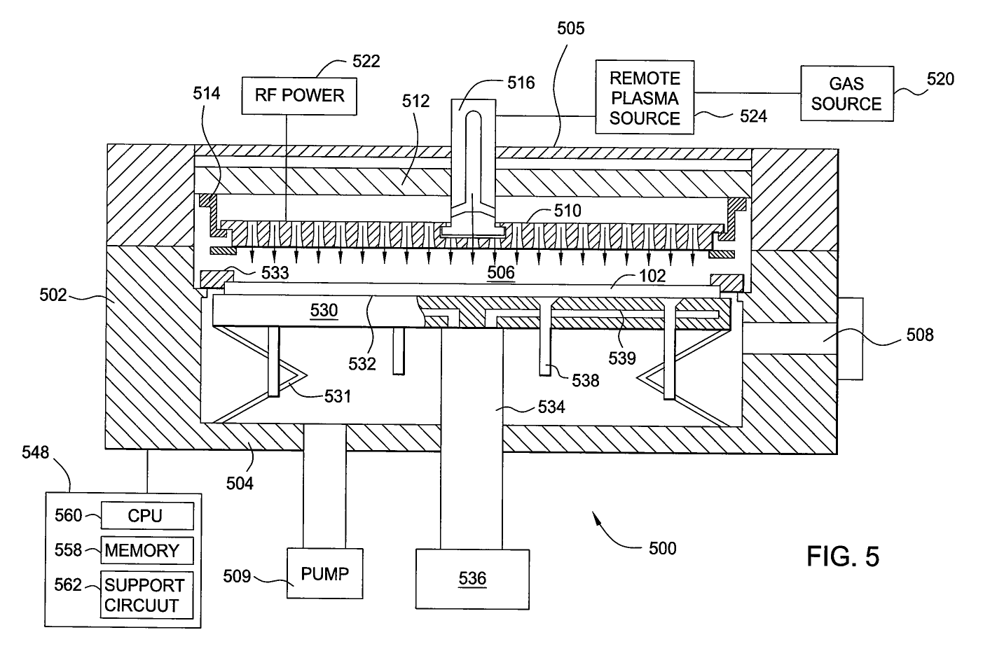

FIG. 5 is a schematic cross-section view of one embodiment of a plasma enhanced chemical vapor deposition (PECVD) chamber 500 in which one or more films of a thin-film solar cell, such as the solar cells of FIGS. 1-4 may be deposited. Particularly, the WSR layers 112, 412 and the pre- and/or post treatment, cleaning or plasma process performed prior to or after the WSR layer deposition process may be formed within the chamber 500 or any other suitable PECVD chamber as necessary. One suitable plasma enhanced chemical vapor deposition chamber is available from Applied Materials, Inc., located in Santa Clara, Calif. It is contemplated that other deposition chambers, including those from other manufacturers, may be utilized to practice the present invention.

The chamber 500 generally includes walls 502, a bottom 504, a lid 505 and substrate support 530 which define a process volume 506. The process volume is accessed through a valve 508 such that the substrate may be transferred in and out of the chamber 500. The substrate support 530 includes a substrate receiving surface 532 for supporting a substrate and stem 534 coupled to a lift system 536 to raise and lower the substrate support 530. A shadow ring 533 may be optionally placed over periphery of the substrate 102. Lift pins 538 are moveably disposed through the substrate support 530 to move a substrate to and from the substrate receiving surface 532. The substrate support 530 may also include heating and/or cooling elements 539 to maintain the substrate support 530 at a desired temperature. The substrate support 530 may also include grounding straps 531 to provide an RF return path at the periphery of the substrate support 530.

A showerhead 510 is coupled to a backing plate 512 at its periphery by a suspension 514. The showerhead 510 may also be coupled to the backing plate by one or more center supports 516 to help prevent sag and/or control the straightness/curvature of the showerhead 510. A gas source 520 is coupled to the backing plate 512 to provide gas through the backing plate 512 and through the showerhead 510 to the substrate receiving surface 532. A vacuum pump 509 is coupled to the chamber 500 to control the process volume 506 at a desired pressure. An RF power source 522 is coupled to the backing plate 512 and/or to the showerhead 510 to provide a RF power to the showerhead 510 to create an electric field between the showerhead and the substrate support 530 so that a plasma may be generated from the gases present between the showerhead 510 and the substrate support 530. Various RF frequencies may be used, such as a frequency between about 0.3 MHz and about 200 MHz. In one embodiment the RF power source is provided at a frequency of 13.56 MHz.

A remote plasma source 524, such as an inductively coupled remote plasma source, may also be coupled between the gas source and the backing plate. Between processing substrates, a cleaning gas may be provided to the remote plasma source 524 so that a remote plasma is generated and provided to clean chamber components. The cleaning gas may be further excited by the RF power source 522 provided to the showerhead. Suitable cleaning gases include, but are not limited to, NF₃, F₂, and SF₆.

The deposition methods for one or more layers, such as one or more of the layers of FIGS. 1-4, may include the following deposition parameters in the process chamber of FIG. 5 or other suitable chamber. A substrate having a surface area of 10,000 cm² or more, such as 40,000 cm² or more, and for example 55,000 cm² or more, is provided to the chamber. It is understood that after processing the substrate may be cut to form smaller solar cells.

In one embodiment, the heating and/or cooling elements 539 may be set to provide a substrate support temperature during deposition of about 400° C. or less, for example between about 100° C. and about 400° C., or between about 150° C. and about 300° C., such as about 200° C.

The spacing during deposition between the top surface of a substrate disposed on the substrate receiving surface 532 and the showerhead 510 may be between 400 mil and about 1,200 mil, such as between 400 mil and about 800 mil.

A controller 548 is coupled to the processing chamber 500. The controller 548 includes a central processing unit (CPU) 460, a memory 558, and support circuits 562. The controller 548 is utilized to control the process sequence, regulating the gas flows from the gas source 520 into the chamber 500 and controlling power supply from the RF power source 522 and the remote plasma source 524. The CPU 560 may be of any form of a general purpose computer processor that can be used in an industrial setting. The software routines can be stored in the memory 558, such as random access memory, read only memory, floppy or hard disk drive, or other form of digital storage. The support circuits 562 are conventionally coupled to the CPU 560 and may comprise cache, clock circuits, input/output subsystems, power supplies, and the like. The software routines, when executed by the CPU 560, transform the CPU into a specific purpose computer (controller) 548 that controls the processing chamber 500 such that the processes, such as described above, are performed in accordance with the present invention. The software routines may also be stored and/or executed by a second controller (not shown) that is located remotely from the processing chamber 500.

Thus, an apparatus and methods for forming a WSR layer with a desired surface roughness in a solar cell device are provided. The method advantageously produces a roughened WSR layer disposed between junctions that has high transparency, low refractive index and desired film surface roughness to enhance light scattering and reflection in the cells. Additionally, the WSR layer also provides adjustable bandgap that can efficiently reflect or absorb light in different wavelengths, thereby increasing the photoelectric conversion efficiency and device performance of the PV solar cell as compared to conventional methods.

While the foregoing is directed to embodiments of the present invention, other and further embodiments of the invention may be devised without departing from the basic scope thereof, and the scope thereof is determined by the claims that follow.

What is claimed is:

1. A method of forming a solar cell device, comprising:
forming a wavelength selective reflector layer between a first p-i-n junction and a second p-i-n junction formed on a substrate; and
performing a post treatment process on the wavelength selective reflector layer to form the uneven surface with the roughness greater than 20 nm.

2. The method of claim 1, wherein forming the uneven surface of the wavelength selective reflector layer further comprises:
texturing a surface of the wavelength selective reflector layer by a texturing process by a hydrogen, helium or argon gas.

3. The method of clam 2, wherein the texturing process is performed by a dry etching process, a wet etching process, a plasma process, a surface treatment process, a particle spray process, or a mechanical process.

4. The method of claim 1, wherein forming the uneven surface of the wavelength selective reflector layer further comprises:
performing a pre-treatment process on a surface of the first p-i-n junction to form a roughened surface thereof;
forming the wavelength selective reflector layer on the roughened surface to follow the roughened surface formed on the first p-i-n junction to create the uneven surface on the wavelength selective reflector layer.

5. The method of claim 4, wherein the pre-treatment process is an argon treatment process or a hydrogen treatment process.

6. The method of claim 1, wherein forming the uneven surface of the wavelength selective reflector layer further comprises:
forming a thin layer of particles on the first p-i-n junction to define an uneven surface prior to the deposition of the wavelength selective reflector layer.

7. The method of claim 6, wherein the particles have a diameter between about 10 nm and about 100 nm.

8. The method of claim 7, wherein the particles are a dielectric material.

9. The method of claim 1, wherein the roughness of the uneven surface of the wavelength selective reflector layer is controlled between about 40 nm and about 60 nm.

10. The method of claim 1, wherein the first p-i-n junction further includes a p-type amorphous silicon layer, an intrinsic type amorphous silicon layer, and an n-type microcrystalline silicon layer.

11. The method of claim 10, wherein the second p-i-n junction further includes a p-doped microcrystalline silicon layer, an intrinsic type microcrystalline silicon layer, and an n-doped amorphous silicon layer adjacent to the intrinsic type microcrystalline silicon layer.

12. A photovoltaic device, comprising:
a wavelength selective reflector layer disposed between a first p-i-n junction and a second p-i-n junction formed on a substrate, wherein the wavelength selective reflector layer has an uneven surface having a surface roughness greater than 20 nm.

13. The photovoltaic device of claim 12, wherein the wavelength selective reflector layer is fabricated from a silicon alloy material.

14. The photovoltaic device of claim 12, wherein a surface on which the wavelength selective reflector layer is deposited as substantially flat.

15. The photovoltaic device of claim 12, further comprising:
a thin layer of particles having an uneven surface formed between the first p-i-n junction and the wavelength selective reflector layer.

16. The photovoltaic device of claim 12, wherein the roughness of the uneven surface of the wavelength selective reflector layer is between about 40 nm and about 60 nm.

17. A method of forming a solar cell device, comprising:
forming a TCO layer on a substrate;
texturing the TCO layer to form a roughened surface thereon, wherein the roughened surface has a surface roughness greater than 22 nm;
forming a first p-i-n junction on the TCO layer;
forming a wavelength selective reflector layer on the first p-i-n junction, wherein the wavelength selective reflector layer having a surface roughness greater than 20 nm; and
forming a second p-i-n junction on the wavelength selective reflector layer.

18. The method of claim 17, further comprising:
performing a pre-treatment process on the first p-i-n junction to create an uneven surface on which the wavelength selective reflector layer is deposited.

19. The method of claim 17, wherein forming the wavelength selective reflector layer further comprises:
performing a post-treatment process on the wavelength selective reflector layer to roughen the surface of the wavelength selective reflector layer.

20. The method of claim 17, wherein the texturing of the TCO layer further comprises:
texturing the surface of the TCO layer by a dry etching process, a wet etching process, a plasma process, a surface treatment process, or a mechanical process.
